(19) United States
(12) Patent Application Publication
(10) Pub. No.: US 2024/0421399 A1
(43) Pub. Date: Dec. 19, 2024

(54) BATTERY PACK

(71) Applicant: SK ON CO., LTD., Seoul (KR)

(72) Inventors: Hwa Kyoo YOON, Daejeon (KR); Sang Tae AN, Daejeon (KR)

(21) Appl. No.: 18/745,967

(22) Filed: Jun. 17, 2024

(30) Foreign Application Priority Data
Jun. 15, 2023 (KR) 10-2023-0076827

(51) Int. Cl. H01M 50/242; H01M 10/42; H01M 10/48; H01M 50/211; H01M 50/284; H01M 50/296

(52) U.S. Cl. CPC H01M 50/242; H01M 10/425; H01M 10/482; H01M 50/211; H01M 50/284; H01M 50/296; H01M 2010/4278

(57) ABSTRACT

A battery pack of the present disclosure includes: a pack housing accommodating a battery module therein; a monitoring portion monitoring the battery module; and a connecting portion provided to transmit an electric signal between the monitoring portion and the battery module, wherein the monitoring portion includes: a circuit portion processing the electrical signal; and a flexible wire electrically connecting the connecting portion and the circuit portion.

### CROSS-REFERENCE TO RELATED PATENT APPLICATION

The present application claims priority under 35 U.S.C. § 119 (a) to Korean patent application number 10-2023-0076827 filed on Jun. 15, 2023, in the Korean Intellectual Property Office, the entire disclosure of which is incorporated by reference herein.

### BACKGROUND OF THE INVENTION

### 1. Field

The present disclosure relates to a battery pack. Specifically, it relates to a battery pack including flexible a wire to prevent damage to a joining portion.

### 2. Description of the Related Art

A secondary battery is a battery that is made to convert electrical energy into chemical energy and store it so that it may be reused multiple times through charging and discharging. Secondary batteries are widely used across industries due to their economical and eco-friendly characteristics. In particular, among secondary batteries, lithium secondary batteries are widely used throughout industries, including portable devices that require high-density energy.

Secondary batteries may be manufactured into battery modules by grouping a plurality of battery cells to have high-output and high-capacity characteristics. In addition, a plurality of battery modules may be grouped and manufactured into a battery pack.

A battery pack may be provided with a battery management system (BMS) to prevent failure due to damage to each battery cell or overcharging. To this end, a battery pack may include a cell monitoring unit (CMU) for transmitting and receiving the status of each battery module.

However, since a CMU is connected to a battery module, there is a risk that it is easily damaged by external shock. In addition, when a battery module and a CMU are connected, defects may occur during the assembly process due to assembly tolerances in the case of a board-to-board type.

### SUMMARY OF THE INVENTION

A problem that the present disclosure aims to solve is to provide a battery pack in which the coupling of a battery module and a CMU may be stably maintained even when external pressure due to vibration or shock is applied.

In addition, space efficiency inside a battery pack may be improved by minimizing the number of CMUs that may each transmit information from adjacent battery modules.

In addition, still another problem that the present disclosure aims to solve is to provide a battery pack in which a battery module and a CMU may be connected to each other through flexible wires even in the presence of an assembly tolerance therebetween.

In addition, the present disclosure can be widely applied in the field of green technology, such as electric vehicles, battery charging stations, solar power generation, and wind power generation using batteries.

In addition, the present disclosure can be used in eco-friendly electric vehicles, hybrid vehicles, etc. to prevent climate change by suppressing air pollution and greenhouse gas emissions.

A battery pack of the present disclosure includes: a pack housing accommodating a battery module therein; a monitoring portion monitoring the battery module; and a connecting portion provided to transmit an electric signal between the monitoring portion and the battery module, wherein the monitoring portion includes: a circuit portion processing the electrical signal; and a flexible wire electrically connecting the connecting portion and the circuit portion.

The circuit portion may include a control portion confirming information including voltage of the battery module through the electric signal and transmitting or receiving the information; and

a joining portion connected to the flexible wire.

The joining portion may be positioned to face the battery module from the circuit portion.

The joining portion and the connecting portion may be positioned to face each other.

The length of the flexible wire may be longer than or equal to the vertical distance between the connecting portion and the joining portion.

The battery module may include a first submodule and a second submodule, each including a plurality of battery cells therein; the connecting portion includes a first connecting portion provided in the first submodule and a second connecting portion provided in the second submodule; and the circuit portion includes a first joining portion and a second joining portion connected to the first connecting portion and the second connecting portion, respectively.

The plurality of battery cells of the first submodule and the plurality of battery cells of the second submodule may be stacked along one direction, and the first submodule and the second submodule may be disposed perpendicularly to the one direction.

The plurality of battery cells of the first submodule and the plurality of battery cells of the second submodule may be stacked along one direction, and the first submodule and the second submodule may be disposed in parallel with the one direction.

The battery pack may be provided with a binding terminal at one end and the other end of the flexible wire, wherein the joining terminal at one end may be connected to a connecting terminal provided at the connecting portion, and the joining terminal at the other end may be connected to a joining portion provided at the circuit portion.

The binding terminal may be detachable.

The connecting portion and the monitoring portion may be detachably coupled.

The connecting portion may include a fastening groove, and the monitoring portion may include a fastening protrusion.

The monitoring portion may further include a protecting portion for covering the circuit portion.

According to the present disclosure, the coupling of a battery module and a CMU may be stably maintained even when external pressure due to vibration or shock is applied.

In addition, another problem that the present disclosure aims to solve is to improve space efficiency inside a battery pack by minimizing the number of CMUs that may each transmit information from adjacent battery modules.

In addition, a battery module and a CMU may be connected to each other through flexible wires even in the presence of an assembly tolerance therebetween.

### BRIEF DESCRIPTION OF THE DRAWINGS

FIG. 1 shows a battery pack according to the present disclosure.

FIG. 2 shows an exploded view of a battery module according to an embodiment of the present disclosure.

FIG. 3 shows an exploded view of a battery module according to another embodiment of the present disclosure.

FIG. 4 shows a battery module according to another embodiment of the present disclosure.

FIG. 5 shows a connecting portion connected to a monitoring portion by a flexible wire according to the present disclosure.

FIG. 6 shows a connecting portion coupled with a monitoring portion of the present disclosure.

### DETAILED DESCRIPTION

Hereinafter, preferred embodiments of the present disclosure will be described in detail with reference to the attached drawings. The configuration or control method of the apparatus described below is only for explaining the embodiments of the present disclosure and is not intended to limit the scope of the present disclosure, and the same reference numerals used throughout the specification indicate the same components.

Specific terms used in the present specification are merely for convenience of explanation and are not used to limit the illustrated embodiments.

For example, expressions such as “same” and “is the same” not only indicate a strictly identical state, but also indicate a state in which there is a difference in tolerance or the degree to which the same function is obtained.

For example, expressions representing relative or absolute arrangement such as “in a certain direction,” “along a certain direction,” “side by side,” “perpendicularly,” “at the center,” “concentric,” or “coaxial,” not only strictly represent the arrangement, but also represent the state of relative displacement with a tolerance, or an angle or distance at which the same function is obtained.

To explain the present disclosure, it will be described below based on a spatial orthogonal coordinate system with X, Y, and Z axes orthogonal to each other. Each axis direction (X-axis direction, Y-axis direction, Z-axis direction) refers to both directions in which each axis extends.

The X-direction, Y-direction, and Z-direction mentioned below are for explanation so that the present disclosure may be clearly understood, and of course, the directions may be defined differently depending on where the reference is placed.

The use of terms such as ‘first, second, and third’ in front of the components mentioned below is only to avoid confusion about the components to which they are referred and is irrelevant to the order, importance, or master-slave relationship between the components, etc. For example, an invention that includes only a second component without a first component may also be implemented.

As used in the present specification, singular expressions include plural expressions unless the context clearly dictates otherwise.

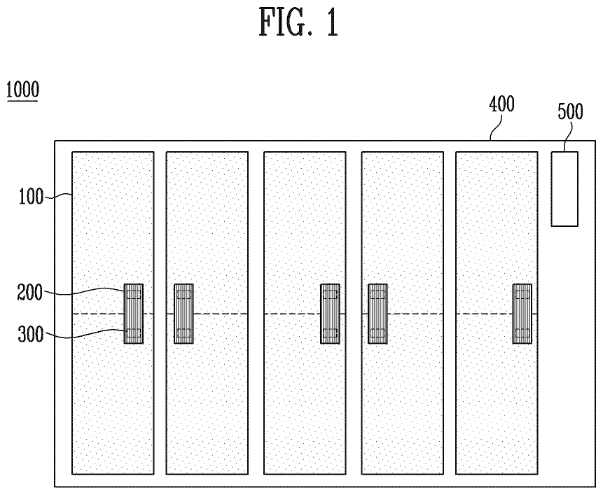

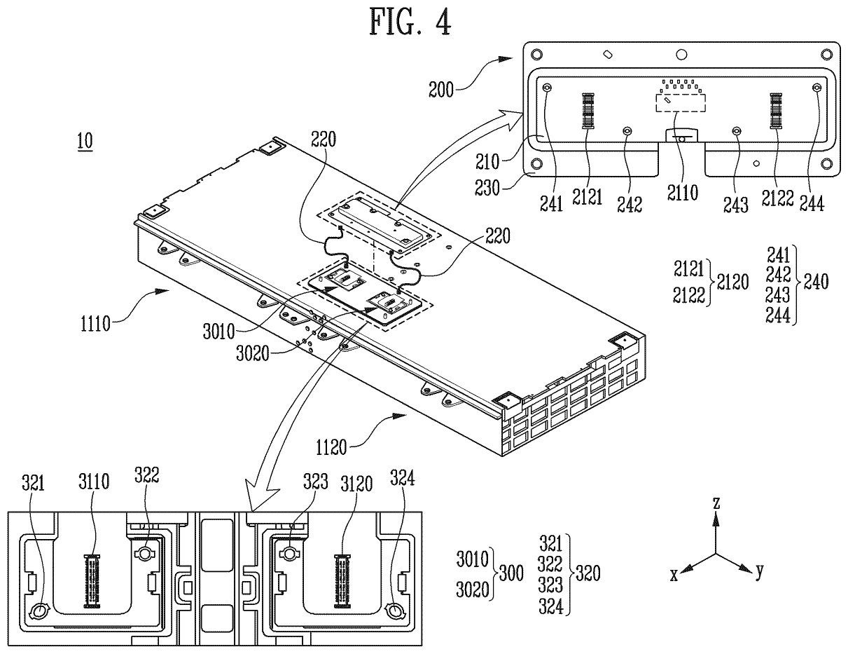

FIG. 1 shows a battery pack 1000 according to the present disclosure. A battery pack 1000 of the present disclosure includes: a pack housing 400 accommodating a battery module 100 therein; a monitoring portion 200 monitoring the battery module 100; and a connecting portion 300 provided to transmit an electric signal between the monitoring portion 200 and the battery module 100, wherein the monitoring portion 200 includes: a circuit portion 210 (in FIG. 4) processing the electrical signal; and a flexible wire 220 (in FIG. 4) electrically connecting the connecting portion 300 and the circuit portion 210.

The battery cell 1 described in the present specification refers to a secondary battery that may be repeatedly used by charging and discharging electrical energy. For example, it may be a lithium secondary battery, but is not limited thereto.

Battery cells may be classified into a pouch-type secondary battery, a prismatic secondary battery, or a cylindrical secondary battery depending on the shape. In the present specification, a pouch-type secondary battery is illustrated as an example for convenience of explanation, but the present invention is not limited thereto.

Main components of a battery cell 1 are a cathode, an anode, a separator, and an electrolyte, and a battery cell may be made by putting the main components into a case (or pouch). A battery cell 1 may further include an electrode lead protruding outside a case for electrical connection to the outside. Electrode leads may each be connected to a cathode and an anode of a battery cell 1.

Meanwhile, a battery module 100 described in the present specification refers to a battery assembly formed by grouping one or more batter cells and placing them into a case to protect them from external shock, heat, vibration, or the like and to provide them with high-output and high-capacity properties.

A battery pack 1000 described in the present specification refers to a set in which a preset number of battery cells 1 or battery modules 100 are collected to obtain a finally desired voltage or output. In the present specification, a battery pack 1000 including battery modules 100 is illustrated for convenience of explanation, but the present invention is not limited thereto.

Referring to FIG. 1, a battery pack 1000 may include a pack housing 400. A pack housing 400 may accommodate one or more battery modules 100 therein. A pack housing 400 may include a material with high mechanical rigidity to protect a battery module 100 from external shock or pressure.

When a battery pack 1000 includes a plurality of battery modules 100, the performance of the battery pack 1000 may vary depending on the state of each battery module.

Therefore, a battery pack 1000 may further include a battery management system 500 for managing a battery module 100 in an optimal state by measuring the performance, lifespan, voltage, current, etc. of the battery module 100. A battery management system 500 may specifically measure and monitor various information about a battery module, including the voltage, current, and temperature of the battery module 100, through a sensing portion (not shown). Specifically, to reduce the deviation between battery cells, a battery management system may perform cell balancing or control the battery cells 1 from being overcharged or overdischarged. A battery management system 500 may be accommodated inside a battery pack 1000 together with a battery module 100.

Meanwhile, for a battery management system to monitor the information of a battery module, a means of measuring the information of the battery module is required. To this end, a battery pack 1000 may include a monitoring portion 200. A monitoring portion 200 may convert the data of a battery module 100 into digital data and transmit it to a battery management system 500. For example, a monitoring portion 200 may be a cell monitoring unit (CMU).

To this end, a monitoring portion 200 includes a circuit portion 210 processing an electrical signal. A circuit portion 210 may include a printed circuit board (PCB). A circuit portion 210 may include a control portion 2110 confirming information including voltage of a battery module 100 through an electric signal and transmitting or receiving the information; and a joining portion 2120 (in FIG. 4) connected to a flexible wire 220. To connect a monitoring portion 200 and a plurality of battery modules 100, joining portions 2120 may be provided in a plural number.

A control portion 2110 may include a microcontroller. A control portion 2110 may transmit information to a battery management system 500 using CAN communication. However, without being limited thereto, various methods may be applied to transmit information.

In order for information of a battery module 100 to be transmitted to a monitoring portion 200, a passage through which the monitoring portion and the battery module may be connected is required. To this end, a battery pack 1000 may further include a connecting portion 300.

A connecting portion 300 may allow a battery module 100 and a monitoring portion 200 to exchange electrical signals with each other. For example, a connecting portion 300 may transmit information about the voltage and temperature of a battery cell 1 included in a battery module 100 to a monitoring portion 200.

Meanwhile, as a connecting portion 300, a low voltage sensing connector may be used.

Low voltage sensing connectors may be packaged through a through-hole type or a surface-mounting type.

When a connecting portion 300 is packaged through a surface-mounting type, a battery module 100 and a monitoring unit 200 may be connected through board-to-board connection. In the case of board-to-board connection, a connector and another connector corresponding thereto need to be directly connected. At this time, assembly is difficult due to assembly tolerances, and even when assembled, damage to the connectors may occur due to external pressure, and transmission of information may be interrupted.

A battery pack 1000 according to the present disclosure may include a flexible wire electrically connecting a connecting portion 300 and a circuit portion 210. Through this, damage to a connecting portion 300 and a battery pack 1000 may be prevented.

A flexible wire 220 may continue to maintain connection between a connecting portion 300 and a circuit portion 210 even when they are forcibly moved due to external pressure. A flexible wire may maintain connection by being bent or curved without being broken even when there is external pressure.

In addition, a flexible wire 220 may efficiently and safely connect a plurality of submodules 110 and a single monitoring portion 200. For example, referring to FIG. 4, a flexible wire 220 may connect connecting portions 3010 and 3020 of two adjacent submodules 1110 and 1120 to a single monitoring portion.

At this time, when connecting in a board-to-board manner, the positions and shapes of the connecting portion and submodules need to be precisely adjusted. The ease of assembly of a battery pack of the present disclosure may be improved by connecting a flexible wire to each of a connecting portion and a joining portion.

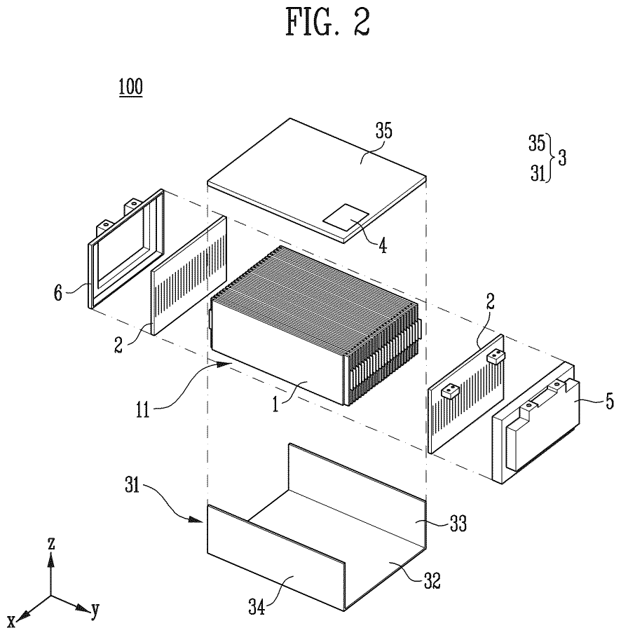

FIG. 2 shows an exploded view of a battery module 100 according to an embodiment of the present disclosure.

Referring to FIG. 2, a battery module 100 according to the present disclosure includes a cell assembly 11 in which a plurality of battery cells 1 are stacked in one direction and a module housing 3 accommodating the cell assembly 11 therein. A module housing 3 is intended to protect a cell assembly 11 from the outside. For example, a plurality of battery cells 1 may be stacked along the X-direction to form a cell assembly 11.

A battery module 100 may further include a bus bar assembly 2 for electrically connecting a plurality of battery cells 1. A bus bar assembly 2 may be electrically connected to the outside and store (or charge) electrical energy in a plurality of battery cells 1, or supply (or discharge) the electric energy stored in the plurality of battery cells 1 to the outside.

A module housing 3 may include a module body 31 including an opening on an upper surface to accommodate a cell assembly 11. A module body 31 may accommodate a cell assembly 11 through an opening.

To this end, a module body 31 may further include a module lower body 32 supporting a cell assembly 11. A module lower body 32 may form a lower surface of a module body 31. A cell assembly 11 may be fixed on a module lower body 32.

A module body 31 may further include a module side body 33 and 34 covering a side surface of a cell assembly 11. A module side body 33 and 34 may be formed to extend upward from both edges of a module lower body 32. A module side body 33 and 34 may be bent at both corners of a module lower body 32 and extend toward a cell assembly 11. For example, a module body 31 may have a ‘U’ shape with both surfaces open along the Y-direction.

A module housing 3 may further include a module cover 35 that is coupled to a module body 31 and closes an opening. A module cover 35 may cover an upper surface of a cell assembly 11. A module housing 3 may be formed by coupling a module body 31 and a module cover 35 into a rectangular parallelepiped shape with both opposing surfaces open.

In addition, a first cover 5 and a second cover 6 closing an opening of a module housing 3 may be included. By coupling a module housing 3 with a first cover 5 and a second cover 6, the battery module 100 may form a hexahedral shape with all surfaces closed.

A module housing 3 may include a through-hole 4 penetrating the inside and outside of the module housing 3. A part of a connecting portion 300 may be exposed to the outside through a through-hole 4. For example, a through-hole 4 may be formed in one area of a module cover 35.

Ultimately, information of a battery module may be transmitted to a monitoring portion 200 through a connecting portion 300 exposed to the outside.

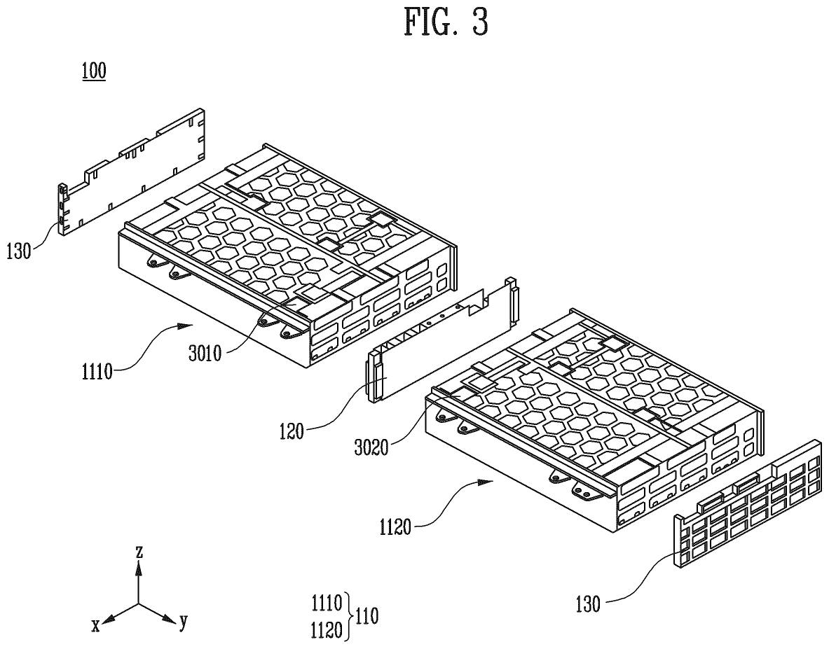

FIG. 3 shows an exploded view of a battery module 100 according to another embodiment of the present disclosure, and FIG. 4 shows a battery module 100 according to another embodiment of the present disclosure.

Referring to FIG. 3, a battery module 100 may include a first submodule 1110 and a second submodule 1120, each including a battery cell 1 therein, a connecting portion 300 may include a first connecting portion 3010 provided in the first submodule 1110 and a second connecting portion 3020 provided in the second submodule 1120; and a circuit portion 210 may include a first joining portion 2121 and a second joining portion 2122 connected to the first connecting portion 3010 and the second connecting portion 3020, respectively.

A battery module 100 may include a plurality of submodules 110 to efficiently manage and control a plurality of battery cells 1 while increasing energy density. A plurality of submodules 110 may include a first submodule 1110 and a second submodule 1120.

In other words, a first sub-module 1110 and a second sub-module 1120 may constitute a battery module. A first sub-module 1110 and a second sub-module 1120 may be individually charged and discharged.

When a battery module 100 includes a plurality of battery cells 1, there may be difficulty in simultaneously monitoring and controlling individual battery cells 1. Therefore, for efficient management of battery cells 1, a plurality of battery cells 1 may be divided into a plurality of groups, and each group may be individually monitored.

Ultimately, a battery module 100 may include a plurality of submodules 110, and each submodule 110 may be separately monitored and controlled.

A submodule 110 may refer to an assembly including a plurality of battery cells 1 and a bus bar assembly 2 electrically connecting the battery cells 1 within a battery module. However, a submodule 110 does not include a housing with high mechanical rigidity that may protect battery cells 1 and a bus bar assembly 2.

In other words, since a submodule 110 is accommodated inside a module housing 3, there may be no need for a separate submodule housing (not shown). Through this, a battery module 100 may be light-weighted.

However, a submodule 110 may further include an insulating cover to group battery cells included in a single submodule group into one unit. It would be appropriate to use a lighter material for an insulating cover than a module housing. An insulating cover may prevent a battery cell included in one submodule from being unintentionally electrically connected to a battery cell included in another submodule within a module housing. In other words, an insulating cover may be a type of submodule 110 cover.

A battery module 100 may further include a center frame 120 and an end frame 130 to prevent collisions between adjacent submodules 110 and to partition a space in which a submodule 110 is accommodated.

Referring to FIG. 3 a first submodule 1110 and a second submodule 1120 may be arranged with the center frame 120 between them. In one embodiment, the plurality of battery cells of the first submodule 1110 and the plurality of battery cells of the second submodule 1120 are stacked along one direction, and the first submodule 1110 and the second submodule 1120 are disposed perpendicularly to the one direction.

In another embodiment, the plurality of battery cells of the first submodule 1110 and the plurality of battery cells of the second submodule 1120 are stacked along one direction, and the first submodule 1110 and the second submodule 1120 are disposed in parallel with the one direction.

A battery pack 1000 may be provided with a plurality of connecting portions 300 connected to each submodule 110 to transmit information on a battery cell 1 included in each submodule 110 to a monitoring portion 200. For example, a first submodule 1110 may include a first connecting portion 3010, and a second submodule 1120 may include a second connecting portion 3020.

In addition, a circuit portion 210 may include a plurality of joining portions 2120 to be connected to a plurality of connecting portions 300. For example, a circuit portion 210 may include a joining portion 2121 and a second joining portion 2122. A first joining portion 2121 may be connected to a first connecting portion 3010, and a second joining portion 2122 may be connected to a second connecting portion 3020.

Referring to FIG. 4, a battery module 100 may include a first submodule 1110 and a second submodule 1120. A first submodule 1110 may be connected to a first connecting portion 3010, and a second submodule 1120 may be connected to a second connecting portion 3020. A first connecting portion 3010 and a second connecting portion 3020 may be exposed to the outside through a through-hole 4 formed on one surface of a module housing 3. A monitoring portion 200 may be connected to a connecting portion 300 exposed to the outside.

A connecting portion 300 may include a connecting terminal 310. A connecting portion 300 may be connected to an external device through a connecting terminal 310. For example, a connecting terminal 310 may be connected to a flexible wire 220.

A first connecting portion 3010 may include a first connecting terminal 3110, and a second connecting portion 3020 may include a second connecting terminal 3120. A first connecting terminal 3110 and a second connecting terminal 3120 may be connected to a first joining portion 2121 and a second joining portion 2122 through a flexible wire 220, respectively.

A monitoring portion 200 may be connected to each of a plurality of submodules 110. A monitoring portion 200 may be connected to a first submodule 1110 and a second submodule 1120 and may monitor information of a battery cell 1 included in each submodule 110.

Referring to FIG. 4, a flexible wire 220 may connect a monitoring portion 200 and a connecting portion 300. A flexible wire 220 may connect a first joining portion 2121 and a first connecting portion 3010 therebetween and may connect a second joining portion 2122 and a second connecting portion 3020 therebetween. Ultimately, a plurality of flexible wires 220 may be provided.

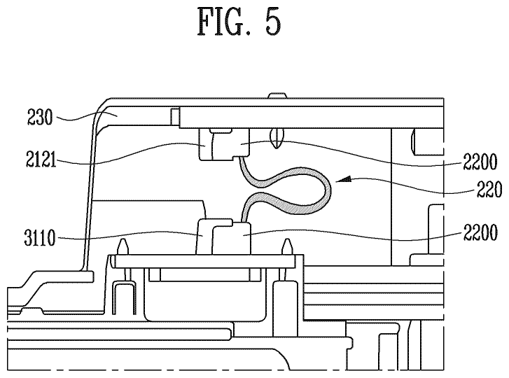

FIG. 5 shows a connecting portion connected to a monitoring portion by a flexible wire according to the present disclosure.

Referring to FIG. 5, a binding terminal 2200 may be provided at both ends of a flexible wire 220. In other words, a binding terminal 2200 may be provided at one end and the other end of a flexible wire 220.

A binding terminal 2200 may be connected to a connecting portion and a circuit portion. A binding terminal 2200 may connect a first connecting portion and a circuit portion. In addition, a binding terminal may connect a second connecting portion and a circuit portion.

For example, referring to FIG. 5, one end of a binding terminal 2200 may be connected to a first connecting terminal 3110 provided at a first connecting portion 3010, and the other end of the binding terminal 2200 may be connected to a first joining portion 2121 provided at a circuit portion 210.

A binding terminal 2200 may be detachable. when damage to a connecting portion 300 or a monitoring portion 200 occurs, a binding terminal may detachable, and so a damaged component may be easily replaced. In other words, the connecting portion 300 and the monitoring portion 200 may be separably coupled.

Referring to FIG. 5, a joining portion 2120 may be positioned to face a battery module 100 from a circuit portion 210. By positioning a joining portion 2120 close to a battery module 100, space efficiency may be increased, and connection stability may be improved. In addition, even when the length of a flexible wire 220 is short, the connection between a joining portion 2120 and a connecting portion 300 may be maintained stably.

In addition, a joining portion 2120 may be positioned to face a connecting portion 300. As described above, at least a part of a connecting portion 300 may be exposed to the outside through a through-hole 4 of a module housing 3. A joining portion 2120 may be formed at a position corresponding to an exposed part of a connecting portion 300 to increase the stability of the connection.

The length of a flexible wire 220 may be longer than or equal to the vertical distance between a connecting portion 300 and a joining portion 2120. By forming the flexible wire 220 to be longer than or equal to the vertical distance, the connection may be maintained even when the distance between a joining portion 2120 and a connecting portion 300 increases.

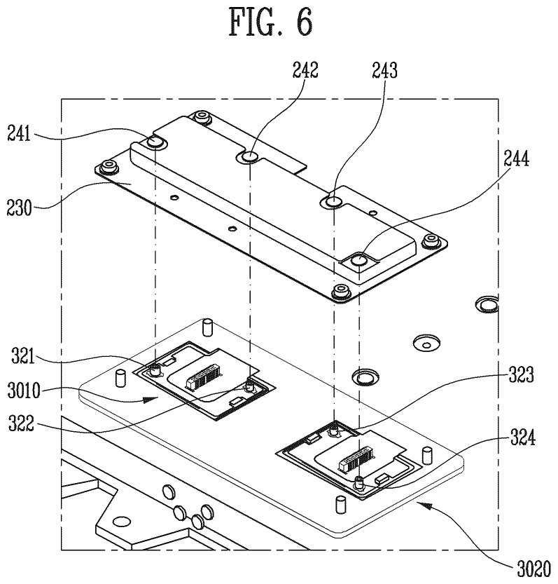

FIG. 6 shows a connecting portion coupled with a monitoring portion of the present disclosure.

A first connecting portion 3010 a second connecting portion 3020 may be coupled with a monitoring portion 200 (in FIG. 4). To this end, a connecting portion may include a fastening groove, and a monitoring portion may include a fastening protrusion. On the contrary, a connecting portion 300 may include a fastening protrusion 240, and a monitoring portion 200 may include a fastening groove 320 so that they may be connected to each other.

As long as a connecting portion 300 and a monitoring portion 200 may be coupled, a method of coupling them is not particularly limited. For example, it would be possible to provide a male thread and a female thread and couple them through screw coupling.

Referring to FIG. 6, a plurality of fastening grooves 320 and fastening protrusions 240 (in FIG. 4) may be provided. For example, a plurality of fastening grooves 321, 322, 323, and 324 may be provided on a connecting portion, and a plurality of fastening protrusions 241, 242, 243, and 244 may be provided on a monitoring portion to be fastened to each other.

For stable coupling of a connecting portion 300 and a monitoring portion 200, fastening grooves may be provided in each of a first connecting portion 3010 and a second connecting portion 3020. For example, a first connecting portion 3010 may be provided with fastening grooves 321 and 322, and a second connecting portion 320 may be provided with fastening grooves 323 and 323.

A monitoring portion 200 may further include a protecting portion 230 to cover a circuit portion 210. A protecting portion may include a recessed portion that is recessed in a direction away from a connecting portion 300 when a monitoring portion is coupled with the connecting portion 300. A circuit portion 210 may be accommodated in a recessed portion.

A control portion 2110 provided in a circuit portion 210 may be provided to face a recessed portion. A joining portion 2120 provided in a circuit portion 210 may be provided to face a battery module. Through this, a control portion may be safely protected even when a circuit portion is damaged due to external pressure.

The present disclosure may be modified and implemented in various forms, and its scope is not limited to the embodiments described above. Therefore, if a modified embodiment includes components of the present disclosure, it should be regarded as falling within the scope of the rights of the present disclosure.

What is claimed is:

1. A battery pack comprising:
a pack housing accommodating a battery module therein;
a monitoring portion monitoring the battery module; and
a connecting portion provided to transmit an electric signal between the monitoring portion and the battery module,
wherein the monitoring portion includes:
a circuit portion processing the electrical signal; and
a flexible wire electrically connecting the connecting portion and the circuit portion.

2. The battery pack according to claim 1, wherein the circuit portion includes:
a control portion confirming information including voltage of the battery module through the electric signal and transmitting or receiving the information; and
a joining portion connected to a flexible wire.

3. The battery pack according to claim 2, wherein the joining portion is positioned to face the battery module from the circuit portion.

4. The battery pack according to claim 3, wherein the joining portion and the connecting portion are positioned to face each other.

5. The battery pack according to claim 4, wherein the length of the flexible wire is longer than or equal to the vertical distance between the connecting portion and the joining portion.

6. The battery pack according to claim 1, wherein the battery module includes a first submodule and a second submodule, each including a plurality of battery cells therein;
the connecting portion includes a first connecting portion provided in the first submodule and a second connecting portion provided in the second submodule; and
the circuit portion includes a first joining portion and a second joining portion connected to the first connecting portion and the second connecting portion, respectively.

7. The battery pack according to claim 6, wherein the plurality of battery cells of the first submodule and the plurality of battery cells of the second submodule are stacked along one direction, and the first submodule and the second submodule are disposed perpendicularly to the one direction.

8. The battery pack according to claim 6, wherein the plurality of battery cells of the first submodule and the plurality of battery cells of the second submodule are stacked along one direction, and the first submodule and the second submodule are disposed in parallel with the one direction.

9. The battery pack according to claim 1, provided with a binding terminal at one end and the other end of the flexible wire, wherein the joining terminal at one end is connected to a connecting terminal provided at the connecting portion, and the joining terminal at the other end is connected to a joining portion provided at the circuit portion.

10. The battery pack according to claim 9, wherein the binding terminal is detachable.

11. The battery pack according to claim 1, wherein the connecting portion and the monitoring portion are detachably coupled.

12. The battery pack according to claim 11, wherein the connecting portion includes a fastening groove, and the monitoring portion includes a fastening protrusion.

13. The battery pack according to claim 1, wherein the monitoring portion further includes a protecting portion for covering the circuit portion.
